(19) United States
(12) Patent Application Publication
(10) Pub. No.: US 2017/0086287 A1
(43) Pub. Date: Mar. 23, 2017

(54) PRINTED CIRCUIT BOARD

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventor: FENG ZHANG, Wuhan (CN)

(21) Appl. No.: 14/879,858

(22) Filed: Oct. 9, 2015

(30) Foreign Application Priority Data
Sep. 17, 2015 (CN) 201510592208.1

(51) Int. Cl. H05K 1/02

(52) U.S. Cl. CPC H05K 1/0213; H05K 2201/0187

(57) ABSTRACT

A printed circuit board includes a high-density distribution area, a line sparse distribution area, a solder mask layer, and a signal layer. A first signal line is laid on the signal layer. The first signal line crosses the high-density distribution area and the line sparse distribution area. The first signal line is narrower in the high-density distribution area than in the line sparse distribution area. A first dielectric constant of the solder mask layer in the high-density distribution area is greater than a second dielectric constant of the solder mask layer in the sparse distribution area.

### FIELD

The subject matter herein generally relates to a printed circuit board that can transmit signals with a high degree of integrity.

### BACKGROUND

Complex chips have a plurality of pins. After a complex chip is attached on a printed circuit board, each pin is connected to an electronic component via a signal line. The signal lines are positioned with high-density around the mounting area of the complex chip. The signal lines on the high-density area are created narrower and a distance between two adjacent signal lines is small, which can allow degradation of the signals.

### BRIEF DESCRIPTION OF THE DRAWINGS

Implementations of the present technology will now be described, by way of example only, with reference to the attached figures.

FIG. 1 is a plan view of an embodiment of a printed circuit board.

FIG. 2 is a cross sectional view along the line II-II of FIG. 1.

FIG. 3 is a cross sectional view along the line III-III of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

The disclosure will now be described in relation to an electronic device with a printed circuit board 10.

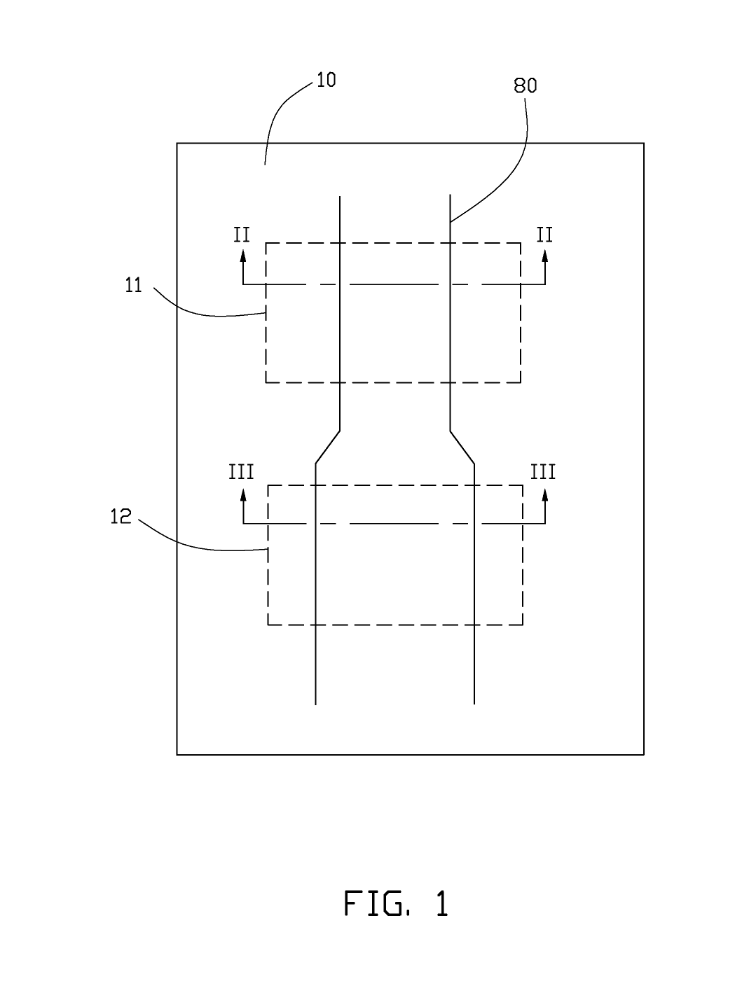

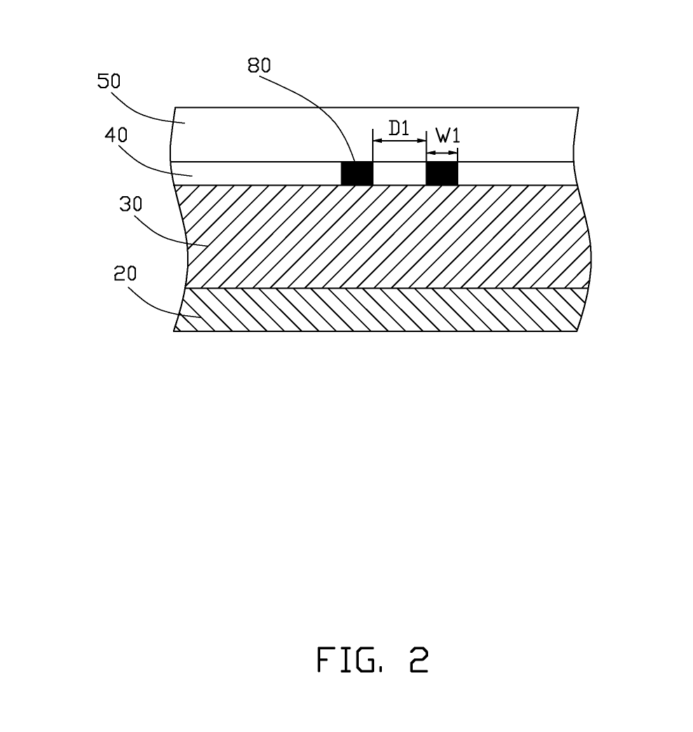

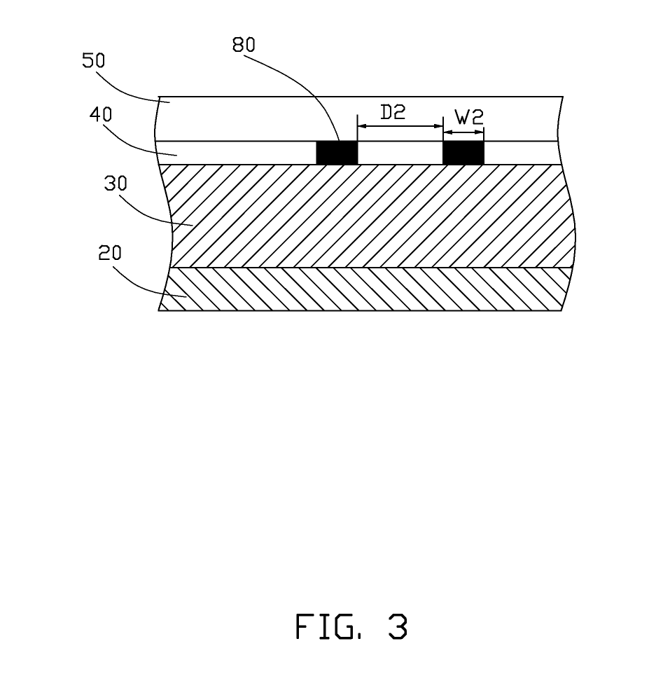

FIGS. 1 to 3 illustrate the printed circuit board 10 includes a ground layer 20, an insulating layer 30, a signal layer 40, and a solder mask layer 50. The ground layer 20 is located on the undermost portion of the printed circuit board 10. The insulating layer 30 is located above the ground layer 20. The signal layer 40 is located above the insulating layer 30. The solder mask layer 50 is located above the signal layer 40 and on the topmost portion of the printed circuit board 10. The two signal lines 80 are located on the signal layer 40.

In the high-density line distribution area 11, a width of each of the two signal lines 80 is set to a first width W1, a distance between the two signal lines 80 is set to a first distance D1, and a dielectric constant of the solder mask layer 50 is set to a dielectric constant first H1.

In the sparse line distribution area 12, a width of each of the two signal lines 80 is set to a second width W2, the distance between the two signal lines 80 is set to a second distance D2, and a dielectric constant of the solder mask layer 50 is set to a second dielectric constant H2.

In the printed circuit board 10, the first width W1 is less than the second width W2, the first distance D1 is less than the second distance D2, and the first dielectric constant H1 is greater than the second dielectric constant H2. . According to transmission line theory, characteristic impedance of the lines can remain same after proper choosing dielectric (Er) for solder masks, even line width is narrower and spacing is small. And, by using high Er solder mask in high-density area 11, noise coupling between lines can be smaller, which is an additional benefit. The above two benefits are essential for a high quality electrical signal transmission path design.

In other embodiments, the printed circuit board 10 can be used in integrated circuit (IC) package.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A printed circuit board comprising:
a high-density distribution area;
a line sparse distribution area;
a solder mask layer having a first dielectric constant of the solder mask layer in the high-density distribution area and a second dielectric constant of the solder mask layer in the line sparse distribution area, wherein the first dielectric constant is greater than the second dielectric constant; and
a signal layer having a first signal line laid thereon, wherein the first signal line crosses the high-density distribution area and the line sparse distribution area, the first signal line is narrower in the high-density distribution area than in the line sparse distribution area.

2. The printed circuit board of claim 1, wherein a second signal line is laid on the signal layer, a distance between the first signal line and the second signal line in the high-density distribution area is set to be a first distance, a distance between the first signal line and the second signal line in the line sparse distribution area is set to be a second distance, and the first distance is less than the second distance.

3. The printed circuit board of claim 1, wherein the signal layer is located below the solder mask layer.

4. The printed circuit board of claim 3, wherein an insulating layer is located below the signal layer.

5. The printed circuit board of claim 4, wherein a ground layer is located below the insulating layer.

6. A printed circuit board, comprising:
a solder mask layer;
a high-density distribution area on which signal lines laid is laid intensively;
a line sparse distribution area on which signal lines laid is laid sparsely;
a first signal line and a second signal line crossing the high-density distribution area and the line sparse distribution area, the first signal line parallel to the first signal line, a distance between the first signal line and the second signal line in the high-density distribution area is set to be a first distance, a distance between the first signal line and the second signal line in the line sparse distribution area is set to be a second distance, and the first distance is less than the second distance, and a first dielectric constant of the solder mask layer in the high-density distribution area is greater than a second dielectric constant of the solder mask layer in the line sparse distribution area.

7. The printed circuit board of claim 6, wherein each of the first signal line and the second signal line is narrower in the high-density distribution area than in the line sparse distribution area.

8. The printed circuit board of claim 6, wherein the first signal line and the second signal line are laid on a signal layer.

9. The printed circuit board of claim 8, wherein the signal layer is located below the solder mask layer.

10. The printed circuit board of claim 9, wherein an insulating layer is located below the signal layer.

11. The printed circuit board of claim 10, wherein a ground layer is located below the insulating layer.
